(19) United States
(12) Patent Application Publication
(10) Pub. No.: US 2013/0045603 A1
(43) Pub. Date: Feb. 21, 2013

(54) SEMICONDUCTOR PROCESS

(71) Applicants: Chao-Yu Tsai, New Taipei City (TW); Chih-Chung Huang, New Taipei City (TW); Tsz-Yuan Chen, Hsinchu City (TW); Kung-Hsun Tsao, Taoyuan County (TW); Huan-Hsin Yeh, Hsinchu County (TW); Yu-Huan Liu, New Taipei City (TW)

(72) Inventors: Chao-Yu Tsai, New Taipei City (TW); Chih-Chung Huang, New Taipei City (TW); Tsz-Yuan Chen, Hsinchu City (TW); Kung-Hsun Tsao, Taoyuan County (TW); Huan-Hsin Yeh, Hsinchu County (TW); Yu-Huan Liu, New Taipei City (TW)

(73) Assignee: UNITED MICROELECTRONICS CORP., Hsinchu (TW)

(21) Appl. No.: 13/213,887

(22) Filed: Aug. 19, 2011

(51) Int. Cl. H01L 21/31

(52) U.S. Cl. 438/703; 438/768; 257/E21.24

(57) ABSTRACT

A semiconductor process is described as follows. A material layer is provided on a substrate. A low-temperature oxidation treatment is performed to the material layer. A photoresist layer is formed on the material layer after the low-temperature oxidation treatment. The photoresist layer is patterned.

### BACKGROUND OF THE INVENTION

1. Field of the Invention

The present invention relates to a semiconductor process, and more particularly, to a lithography process.

2. Description of Related Art

Along with rapid progress of semiconductor technology, dimensions of semiconductor devices are reduced and integrity thereof is promoted continuously to further advance the operating speed and performance of integrated circuits (ICs). In the semiconductor fabrication, for patterning each film or implanting partial areas with dopant, the scope and the critical dimension (CD) thereof are defined by the lithography process. Accordingly, the lithography process plays a significant role in the entire fabrication process.

For example, a patterned photoresist layer is generally formed on a target layer through the lithography process. A dry etching process or a wet etching process is then performed with the patterned photoresist layer as an etching mask, so that the patterns of the patterned photoresist layer are transferred to the target layer thereunder. As the devices are continuously miniaturized and integrated, the design of the ICs becomes increasingly complicated, such that accuracy of the pattern transferring is quite important. Hence, any defect formed in the patterned photoresist layer has to be considered to avoid a great impact on the device performance.

### SUMMARY OF THE INVENTION

Accordingly, the present invention is directed to a semiconductor process, so as to improve accuracy of the pattern transferring and thereby ensure the device reliability and yield.

A semiconductor process of the present invention is described as follows. A material layer is provided on a substrate. A low-temperature oxidation treatment is performed to the material layer. A photoresist layer is formed on the material layer after the low-temperature oxidation treatment. The photoresist layer is patterned.

Another semiconductor process of the present invention is described as follows. A material layer is provided on a substrate. A first photoresist layer is formed on the material layer. The first photoresist layer is removed by wet stripping. A low-temperature oxidation treatment is performed to the material layer. A second photoresist layer is formed on the material layer after the low-temperature oxidation treatment. The second photoresist layer is patterned.

According to an embodiment of the present invention, the low-temperature oxidation treatment is performed at a temperature within a range of 20° C. to 200° C.

According to an embodiment of the present invention, the low-temperature oxidation treatment is performed at a temperature within a range of 20° C. to 35° C.

According to an embodiment of the present invention, the low-temperature oxidation treatment includes using oxygen-containing plasma without fluorine species. A gas source used for the oxygen-containing plasma can include O₂. In another embodiment, a gas source used for the oxygen-containing plasma consists of O₂.

According to an embodiment of the present invention, the material layer includes a metal-containing material selected from the group consisting TiN, TiAlₓ, TaN, TaC, TaCN, TaCNO and Al.

According to an embodiment of the present invention, the first photoresist layer is removed by using N-methyl-2-pyrrolidone (NMP) and acetone.

According to an embodiment of the present invention, the semiconductor process further includes a jet cleaning step after performing the low-temperature oxidation treatment but before forming the second photoresist layer.

As mentioned above, in the semiconductor process of the present invention, the low-temperature oxidation treatment is conducted before the formation of the photoresist layer or the second photoresist layer. Accordingly, risks of pattern slip and precipitation of the material layer due to the process thermal effect can be reduced efficiently, so as to improve the pattern accuracy and the yield.

In order to make the aforementioned and other features and advantages of the present invention more comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart illustrating a semiconductor process according to a first embodiment of the present invention.

FIGS. 2A-2B depict, in a cross-sectional view, a semiconductor process according to a first embodiment of the present invention.

FIG. 3 schematically illustrates a phase diagram of Al—Cu system with variations in Cu content and temperature.

FIG. 4 is a flow chart illustrating a semiconductor process according to a second embodiment of the present invention.

FIGS. 5A-5D depict, in a cross-sectional view, a semiconductor process according to a second embodiment of the present invention.

FIGS. 6A-6D depict, in a cross-sectional view, a semiconductor process according to a third embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

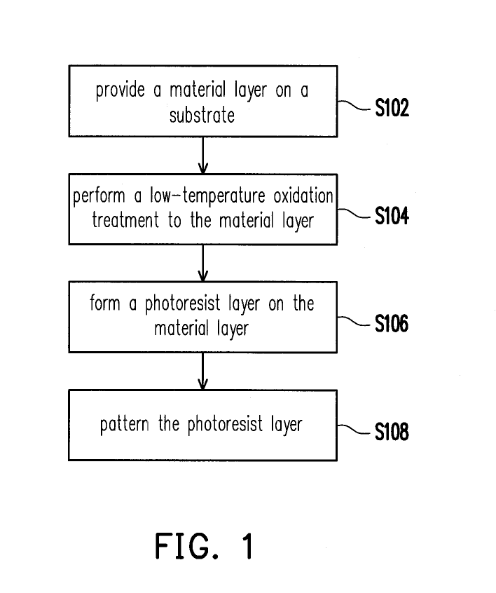

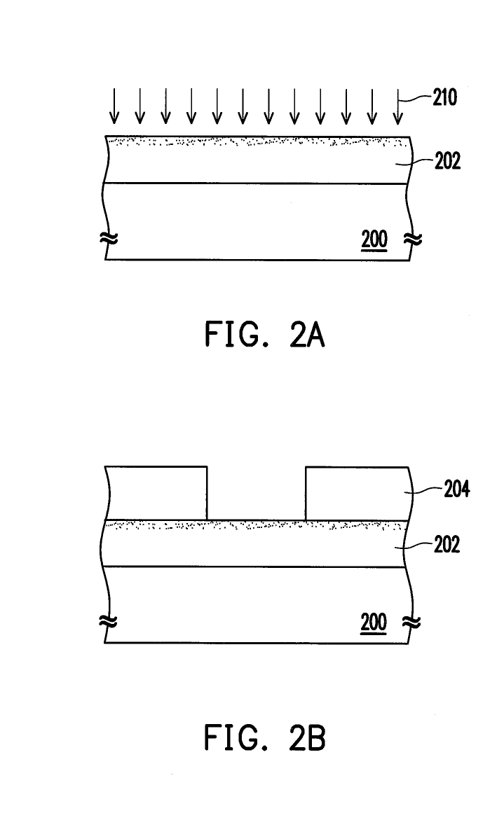

FIG. 1 is a flow chart illustrating a semiconductor process according to a first embodiment of the present invention. FIGS. 2A-2B depict, in a cross-sectional view, a semiconductor process according to a first embodiment of the present invention.

Referring to FIGS. 1 and 2A, in step S102, a substrate 200 is provided, and a material layer 202 is then formed on the substrate 200. The substrate 200 can be a semiconductor wafer, e.g. an N- or a P-type silicon wafer, whereon thin films, conductive parts, or even semiconductor devices may be formed. It is mentionable that the material layer 202 can be a barrier layer or a conductive layer in an interconnection structure or, in the alternative, a work function metal layer in a metal gate structure, depending on where patterns are to be formed. In an embodiment, the material layer 202 may include a metal-containing material selected from the group consisting TiN, TiAlₓ, TaN, TaC, TaCN, TaCNO and Al. Moreover, in an exemplary embodiment, a film which may be made of Al is further included under the material layer 202.

In step S104, a low-temperature oxidation treatment 210 is performed to the material layer 202. In details, the low-temperature oxidation treatment 210 can be conducted at a temperature within a range of about 20° C. to about 200° C., possibly within a range of 20° C. to 35° C. In an exemplary embodiment, the low-temperature oxidation treatment 210 may be carried out at about 30° C., even at room temperature. It should be noticed that the operating temperature range of the low-temperature oxidation treatment 210 may depend upon capabilities of the processing apparatus and also upon material properties of the material layer 202 and the film under the material layer 202.

In an embodiment, the low-temperature oxidation treatment 210 may be implemented in a dry manner, for example, by using oxygen-containing plasma without fluorine species for oxidation. A gas source for the oxygen-containing plasma can include O₂, but any gas containing fluorine sources is excluded from the gas source. In other words, fluorine species are excluded from the oxygen-containing plasma utilized in the low-temperature oxidation treatment 210. In an exemplary embodiment, the foregoing gas source for the oxygen-containing plasma merely includes O₂ without other gases. When using O₂ as the only gas source for the oxygen-containing plasma, a flow rate thereof can be about 500 sccm. In practice, the low-temperature oxidation treatment 210 using the oxygen-containing plasma can be carried out under a pressure of about 300 mTorr, and radio frequency (RF) power applied for generating the plasma may be within a range of 135 W to 400 W, possibly about 185 W. Duration of conducting the plasma oxidation step can last for about 180 seconds.

Referring to FIGS. 1 and 2B, in step S106, a photoresist layer 204 is formed on the material layer 202 after the low-temperature oxidation treatment 210. The photoresist layer 204 can be made of an ordinary photoresist material utilized for the lithography process, such as deep ultraviolet (DUV) photoresist. Afterwards, in step S108, the photoresist layer 204 is patterned as desired. The photoresist layer 204 can be patterned by an exposure step and a successive development step, that is, an ordinary well-known lithography process. The resultant patterned photoresist layer 204 then serves as a mask for patterning the material layer 202 in the subsequent process.

Even if there is no additional anti-reflective coating intervening between the material layer 202 and the photoresist layer 204, the resultant patterned photoresist layer 204 can still be well-defined without suffering from pattern slip issue. The reason that arrives at this result can be attributed to the low-temperature oxidation treatment 210 prior to the formation of the photoresist layer 204. In other words, the low-temperature oxidation treatment 210 may slightly oxidize the upper surface of the material layer 202, and therefore, the material layer 202 is provided with analogous anti-reflective functions on its oxidized upper surface. Accordingly, the oxidized upper surface of the material layer 202 can prevent reflection of the material layer 202 during performing the lithography process, thereby significantly improving pattern accuracy of the resultant patterned photoresist layer 204.

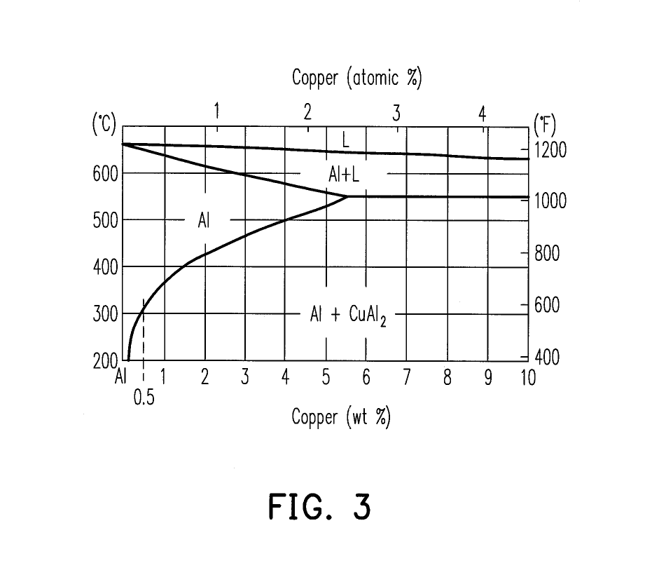

In addition, when the film under the material layer 202 is made of Al, a small amount of Cu is usually added in Al deposition for better electrical performance. As shown in FIG. 3, a phase diagram of Al—Cu system is illustrated with variations in Cu content and temperature. It is obvious that if 0.5 wt % of Cu is contained in the Al film, CuAl₂ precipitation is prone to form on the surface of the Al film when the temperature reaches 300° C. or above, as designated by “Al+CuAl₂” in the Al—Cu phase diagram. That is to say, as the process temperature rises, the risk of precipitating CuAl₂ increases significantly. This CuAl₂ precipitation due to the process thermal effect may act as a hard mask in the successive patterning step of the material layer 202, and thus would cause residual formation in the required patterns which induces bridging issues, wafer scrape in wafer acceptance test (WAT) or even yield loss. In light of the foregoing regards, since the low-temperature oxidation treatment 210 in this embodiment is implemented below 200° C., the risk of CuAl₂ precipitation can be reduced efficiently, thereby mitigating the WAT shift and ameliorating the yield.

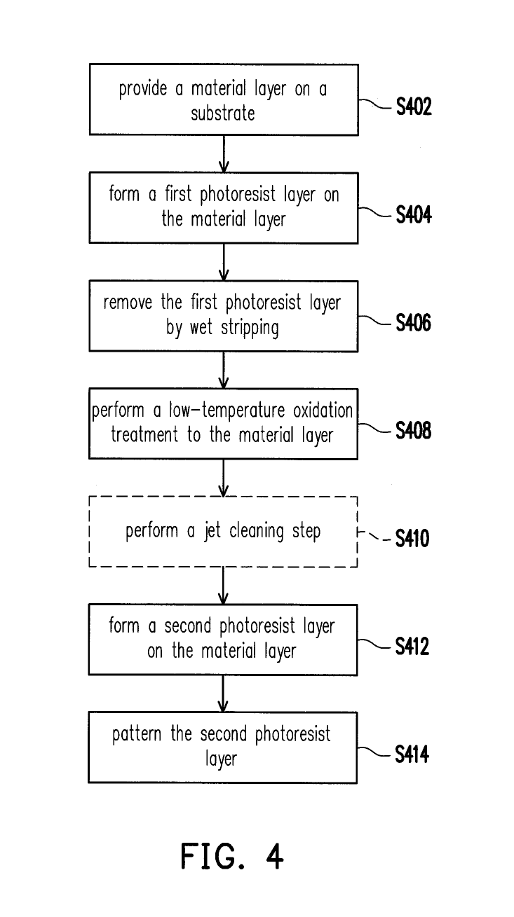

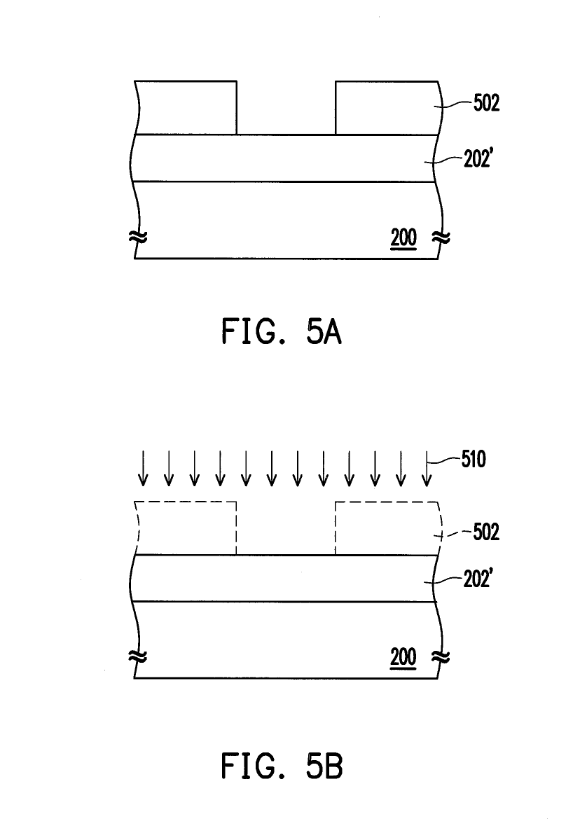

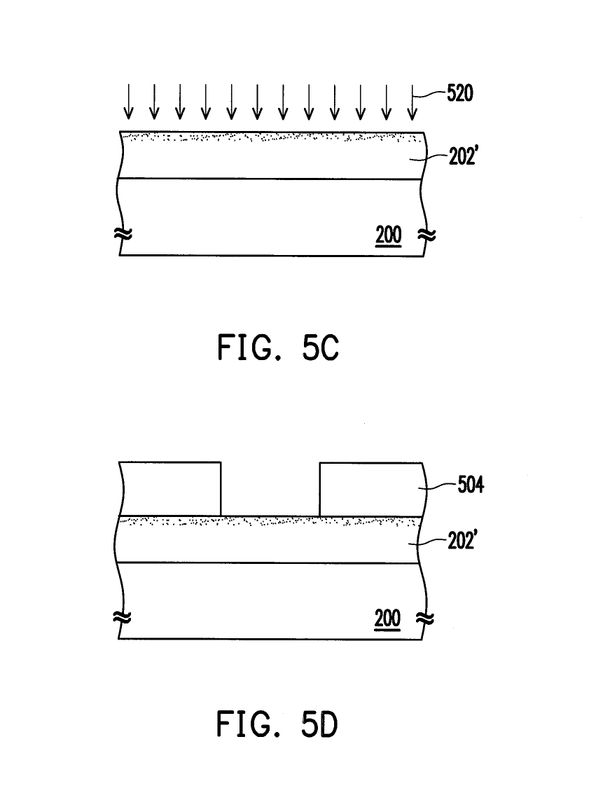

FIG. 4 is a flow chart illustrating a semiconductor process according to a second embodiment of the present invention. FIGS. 5A-5D depict, in a cross-sectional view, a semiconductor process according to a second embodiment of the present invention, wherein the elements identical with those in FIGS. 2A-2B are designated with the same reference numbers, and detailed descriptions of the same or like elements are omitted hereinafter.

Referring to FIGS. 4 and 5A, in step S402, the material layer 202′ is provided on the substrate 200. In step S404, a first photoresist layer 502 is then formed on the material layer 202′. The first photoresist layer 502 can be made of an ordinary photoresist material utilized for the lithography process, such as DUV photoresist. In general, after the formation of the first photoresist layer 502 for proceeding further fabricating processes, an inspection step may be performed in advance to ensure the pattern accuracy or other properties of the first photoresist layer 502. When defects are found in the first photoresist layer 502 whether in pattern or in CD, a rework process should be conducted.

Referring to FIGS. 4 and 5B, in step S406, the first photoresist layer 502 is then removed by wet stripping 510. In practice, an organic solvent may be utilized for the wet stripping 510, so as to substantially remove the majority or the entirety of the first photoresist layer 502. In an embodiment, the organic solvent for removing the first photoresist layer 502 in the wet stripping 510 can be N-methyl-2-pyrrolidone (NMP) and acetone.

Referring to FIGS. 4 and 5C, in step S408, a low-temperature oxidation treatment 520 is performed to the material layer 202′. The low-temperature oxidation treatment 520 can be conducted at a temperature within a range of about 20° C. to about 200° C., possibly within a range of 20° C. to 35° C. In an exemplary embodiment, the low-temperature oxidation treatment 520 may be carried out at about 30° C., even at room temperature. Likewise, the low-temperature oxidation treatment 520 is implemented by oxygen-containing plasma without fluorine species. It should be aware that other details of the low-temperature oxidation treatment 520 can be carried out in a similar or the same manner of the above-mentioned low-temperature oxidation treatment in step S104 of FIG. 1.

After the step S408, a jet cleaning step can be optionally conducted (step S410). The jet cleaning step is carried out, for example, by high-pressure water jet to remove contaminants or particles remained on the material layer 202′. Accordingly, surface cleanness of the material layer 20T can be guaranteed, thereby facilitating desirable formation of the subsequent patterned photoresist layer.

Referring to FIGS. 4 and 5D, in step S412, a second photoresist layer 504 is formed on the material layer 202′. The second photoresist layer 504 can be made of an ordinary photoresist material utilized for the lithography process, such as DUV photoresist. The second photoresist layer 504 is then patterned, for example, by exposure and successive development (step S414). Thus, the resultant second photoresist layer 504 is formed with required patterns, and may function as an etching mask for patterning the material layer 202′ in the subsequent process.

It should be noticed that the defective first photoresist layer 502 may be substantially removed in its completeness by wet stripping 510, and the following low-temperature oxidation treatment 520 mainly aims at oxidizing the upper surface of the material layer 202′. The oxidized surface of the material layer 202′ can have anti-reflective functions as usual anti-reflective coatings, and thereby the second photoresist layer 504 can be formed and patterned well on the material layer 202′ even without an additional anti-reflective coating intervening therebetween. Since the low-temperature oxidation treatment 520 is implemented below 200° C. before the formation of the second photoresist layer 504, the pattern slip issue is eliminated and the probable CuAl₂ precipitation is also lessened significantly. Hence, not only the yield can be guaranteed, but cycle time of the lithography rework process can be shortened.

Moreover, in an exemplary embodiment, the above-mentioned semiconductor process can be applied to the back end of line (BEOL). In the field of metal interconnection fabrication, a practical application of the rework process according to this invention is provided hereinafter. It is to be understood that the following procedures are intended to explain the photolithography rework for defining the topmost metal layer in the metal interconnection structure based on the foregoing semiconductor process and thereby enable those of ordinary skill in the art to practice this invention, but are not construed as limiting the scope of this invention. It is appreciated by those of ordinary skill in the art that other elements, such as the substrate, plugs, wires or dielectric films, can be arranged and formed in a manner or in an amount not shown in the illustrated embodiment according to known knowledge in the art.

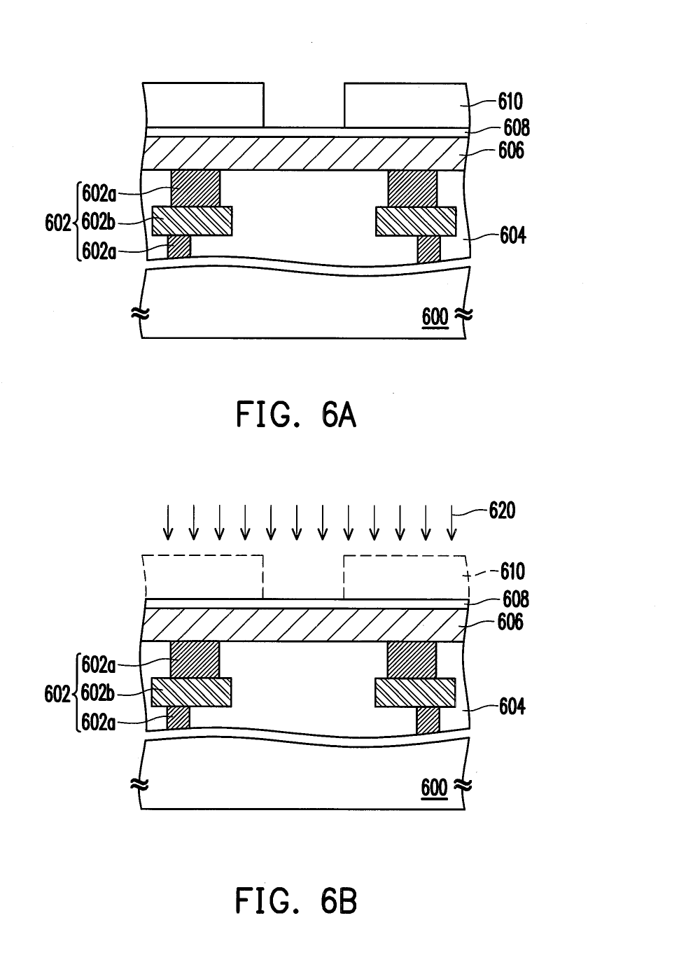

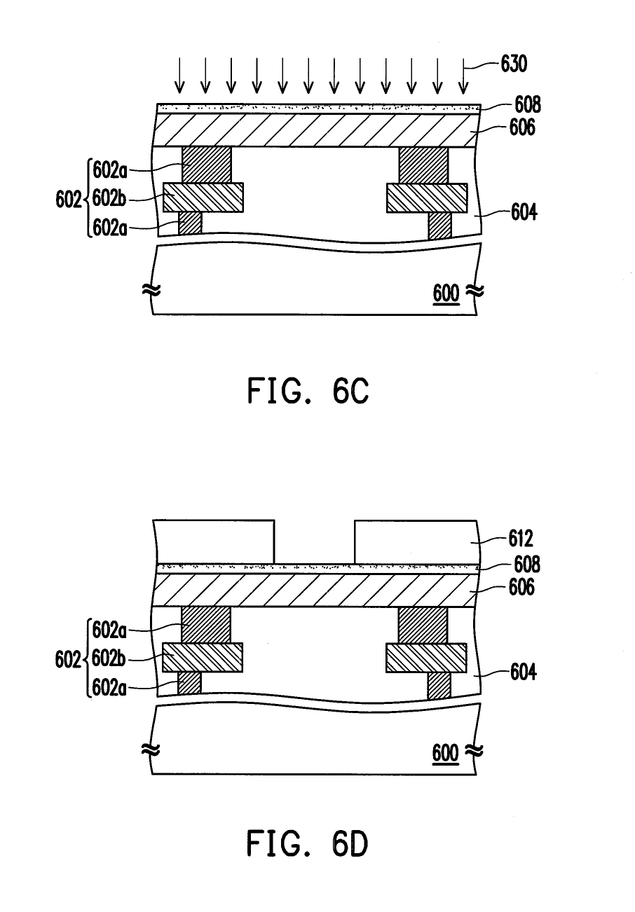

FIGS. 6A-6D depict, in a cross-sectional view, a semiconductor process according to a third embodiment of the present invention.

Referring to FIG. 6A, a substrate 600 is provided, and thin films, conductive parts or known semiconductor devices may be formed on or in the substrate 600. A metallization process is then conducted to form an interconnection structure 602 in the dielectric layer 604 on the substrate 600. The interconnection structure 602 may includes conductive plugs 602a and wires 602b, which are made of Cu and fabricated by, for example, damascene or dual damascene processes. The dielectric layer 604 can be composed of a plurality of dielectric films, and material thereof is, for example, selected from the group consisting of SiO, SiN, SiON, SiCN, a low-k material with a dielectric constant less than 4 and fluorinated silicate glass (FSG). Afterwards, a metal layer 606, a barrier layer 608 and a first photoresist layer 610 are formed sequentially on the interconnection structure 602 and the dielectric layer 604. The metal layer 606 may be made of Al. The barrier layer 608 may be composed of a metal-containing material selected from the group consisting TiN, TiAlₓ, TaN, TaC, TaCN, TaCNO and Al. In an embodiment, the barrier layer 608 can be a single layer of Ti, Ta, TiN or TaN, or a stacked structure of Ti/TiN or Ta/TaN. The first photoresist layer 610 is, for example, DUV photoresist.

Referring to FIG. 6B, if the first photoresist layer 610 is found to have defects, a rework process is required for re-forming a desirable photoresist layer. Thus, the first photoresist layer 610 is then removed by wet stripping 620, such that the majority or the entirety of the first photoresist layer 610 can be substantially stripped away from the surface of the barrier layer 608. In an embodiment, an organic solvent, such as N-methyl-2-pyrrolidone (NMP) and acetone, may be utilized for removing the first photoresist layer 610.

Referring to FIG. 6C, a low-temperature oxidation treatment 630 is performed to the barrier layer 608. The low-temperature oxidation treatment 630 may be implemented in accordance with the description of step S408 in FIG. 4. The method for conducting the low-temperature oxidation treatment 630 can be well appreciated by persons skilled in the art based on the above-mentioned embodiments, and thus, the detailed descriptions thereof are not described herein.

It is noticed that a jet cleaning step can be optionally conducted after the low-temperature oxidation treatment 630. The jet cleaning step is carried out by high-pressure water jet to remove contaminants or particles remained on the barrier layer 608, and therefore, surface cleanness of the barrier layer 608 can be enhanced effectively.

Referring to FIG. 6D, a second photoresist layer 612 is formed on the barrier layer 608. The second photoresist layer 612 can be made of DUV photoresist. The second photoresist layer 612 is then patterned by exposure and development in sequence, so that the required photoresist patterns are formed for functioning as an etching mask to define the barrier layer 608 and the underneath metal layer 606 in the subsequent process.

Since the removal of the defective first photoresist layer 610 is implemented by wet stripping 620, the following low-temperature oxidation treatment 630 mainly aims at slightly oxidizing the upper surface of the barrier layer 608, e.g. the topmost TiN film. The oxidized part of the barrier layer 608 may act as a conventional anti-reflective coating, and the second photoresist layer 612 can thus be formed and patterned well on the barrier layer 608 even without an additional anti-reflective coating. Furthermore, during the lithography rework process, the low-temperature oxidation treatment 630 is implemented below 200° C. before the formation of the second photoresist layer 612, the risks of the pattern slip and the CuAl₂ precipitation can be lessened efficiently. Accordingly, the pattern accuracy of the resultant second photoresist layer 612 and the yield can be improved with the shortened cycle time in this embodiment.

In view of the above, the semiconductor process according to several embodiments described above has at least the following advantages.

1. Since the semiconductor process of the present invention includes the low-temperature oxidation treatment as a pre-treatment prior to the formation of the photoresist layer, the portions pre-treated by the low-temperature oxidation treatment is provided with analogous anti-reflective functions. Therefore, the resultant patterned photoresist layer can be well-defined even without extra anti-reflective coatings under the photoresist layer, thereby ensuring the pattern accuracy of the resultant patterned photoresist layer.

2. The semiconductor process of the present invention utilizes the wet stripping process for removing the majority or the entirety of the first photoresist layer, and then conducts the low-temperature oxidation treatment prior to the formation of the second photoresist layer. Accordingly, the pattern slip and the probable CuAl₂ precipitation issues can be mitigated significantly, and the rework cycle time can be shortened as well.

3. The semiconductor process of the present invention can be widely applied to the various patterned photoresist: formation or reworking, especially the general processes involving metal patterning, and can be integrated with the existing semiconductor techniques. This semiconductor process is not only simple, but can also improve the reliability and yield effectively.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor process, comprising:
providing a material layer on a substrate;
performing a low-temperature oxidation treatment to the material layer;
forming a photoresist layer on the material layer after the low-temperature oxidation treatment; and
patterning the photoresist layer.

2. The semiconductor process according to claim 1, wherein the low-temperature oxidation treatment is performed at a temperature within a range of 20° C. to 200° C.

3. The semiconductor process according to claim 1, wherein the low-temperature oxidation treatment is performed at a temperature within a range of 20° C. to 35° C.

4. The semiconductor process according to claim 1, wherein the low-temperature oxidation treatment comprises using oxygen-containing plasma without fluorine species.

5. The semiconductor process according to claim 4, wherein a gas source used for the oxygen-containing plasma comprises O₂.

6. The semiconductor process according to claim 4, wherein a gas source used for the oxygen-containing plasma consists of O₂.

7. The semiconductor process according to claim 1, wherein the material layer comprises a metal-containing material selected from the group consisting TiN, TiAlₓ, TaN, TaC, TaCN, TaCNO and Al.

8. A semiconductor process, comprising:
providing a material layer on a substrate;
forming a first photoresist layer on the material layer;
removing the first photoresist layer by wet stripping;
performing a low-temperature oxidation treatment to the material layer;
forming a second photoresist layer on the material layer after the low-temperature oxidation treatment; and
patterning the second photoresist layer.

9. The semiconductor process according to claim 8, wherein the low-temperature oxidation treatment is performed at a temperature within a range of 20° C. to 200° C.

10. The semiconductor process according to claim 8, wherein the low-temperature oxidation treatment is performed at a temperature within a range of 20° C. to 35° C.

11. The semiconductor process according to claim 8, wherein the low-temperature oxidation treatment comprises using oxygen-containing plasma without fluorine species.

12. The semiconductor process according to claim 11, wherein a gas source used for the oxygen-containing plasma comprises O₂.

13. The semiconductor process according to claim 11, wherein a gas source used for the oxygen-containing plasma consists of O₂.

14. The semiconductor process according to claim 8, wherein removing the first photoresist layer by using N-methyl-2-pyrrolidone (NMP) and acetone.

15. The semiconductor process according to claim 8, further comprising a jet cleaning step after performing the low-temperature oxidation treatment but before forming the second photoresist layer.

16. The semiconductor process according to claim 8, wherein the material layer comprises a metal-containing material selected from the group consisting TiN, TaN, TaC, TaCN, TaCNO and Al.
